(19) United States
(12) Patent Application Publication
(10) Pub. No.: US 2016/0099304 A1
(43) Pub. Date: Apr. 7, 2016

(54) MoNx as a Top Electrode for TiOx Based DRAM Applications

(71) Applicant: Intermolecular, Inc., San Jose, CA (US)

(72) Inventor: Monica Mathur, San Jose, CA (US)

(21) Appl. No.: 14/507,462

(22) Filed: Oct. 6, 2014

(51) Int. Cl. H01L 49/02

(52) U.S. Cl. CPC H01L 28/75

(57) ABSTRACT

A capacitor stack includes a base bottom electrode layer including a conductive metal nitride material. A second bottom electrode layer is formed above the first bottom electrode layer. The second bottom electrode layer includes a conductive metal oxide material, wherein the crystal structure of the conductive metal oxide material promotes a desired high-k crystal phase of a subsequently deposited dielectric layer. A dielectric layer is formed above the second bottom electrode layer. A molybdenum nitride or a molybdenum oxy-nitride layer is formed above the dielectric layer. A fourth top electrode layer is formed above the third top electrode layer. The base top electrode layer includes a conductive metal nitride material.

### TECHNICAL FIELD

The present disclosure relates generally to the field of dynamic random access memory (DRAM), and more particularly to methods of forming a capacitor stack for improved DRAM performance.

### BACKGROUND

Dynamic Random Access Memory utilizes capacitors to store bits of information within an integrated circuit. A capacitor is formed by placing a dielectric material between two electrodes formed from conductive materials. A capacitor's ability to hold electrical charge (i.e., capacitance) is a function of the surface area of the capacitor plates A, the distance between the capacitor plates d, and the relative dielectric constant or k-value of the dielectric material. The capacitance is given by:

$$C = {κɛ}_{o} \frac{A}{d} \qquad ( Eqn . 1 )$$

where εₒ represents the vacuum permittivity.

The dielectric constant is a measure of a material's polarizability. Therefore, the higher the dielectric constant of a material, the more electrical charge the capacitor can hold. Therefore, for a given desired capacitance, if the k-value of the dielectric is increased, the area of the capacitor can be decreased to maintain the same cell capacitance. Reducing the size of capacitors within the device is important for the miniaturization of integrated circuits. This allows the packing of millions (mega-bit (Mb)) or billions (giga-bit (Gb)) of memory cells into a single semiconductor device. The goal is to maintain a large cell capacitance (generally ˜10 to 25 fF) and a low leakage current density (generally <10⁻⁷ A cm⁻²). The physical thickness of the dielectric layers in DRAM capacitors cannot be reduced without limit because leakage current caused by tunneling mechanisms exponentially increases as the thickness of the dielectric layer decreases.

Traditionally, SiO₂ has been used as the dielectric material and semiconducting materials (semiconductor-insulator-semiconductor [SIS] cell designs) have been used as the electrodes. The cell capacitance was maintained by increasing the area of the capacitor using very complex capacitor morphologies while also decreasing the thickness of the SiO₂ dielectric layer. Increases of the leakage current above the desired specifications have demanded the development of new capacitor geometries, new electrode materials, and new dielectric materials. Cell designs have migrated to metal-insulator-semiconductor (MIS) and now to metal-insulator-metal (MIM) cell designs for higher performance.

Typically, DRAM devices at technology nodes of 80 nm and below use MIM capacitors wherein the electrode materials are metals. These electrode materials generally have higher conductivities than the semiconductor electrode materials, higher work functions, exhibit improved stability over the semiconductor electrode materials, and exhibit reduced depletion effects. The electrode materials must have high conductivity to ensure fast device speeds. Representative examples of electrode materials for MIM capacitors are metals, conductive metal oxides, conductive metal silicides, conductive metal nitrides (i.e. titanium nitride), or combinations thereof. MIM capacitors in these DRAM applications utilize insulating materials having a dielectric constant, or k-value, significantly higher than that of SiO₂ (k=3.9). For DRAM capacitors, the goal is to utilize dielectric materials with k-values greater than about 40. Such materials are generally classified as high-k materials. Representative examples of high-k materials for MIM capacitors are non-conducting metal oxides, non-conducting metal nitrides, non-conducting metal silicates or combinations thereof. These dielectric materials may also include additional dopant materials.

A figure of merit in DRAM technology is the electrical performance of the dielectric material as compared to SiO₂ known as the Equivalent Oxide Thickness (EOT). A high-k material's EOT is calculated using a normalized measure of silicon dioxide (SiO₂ k=3.9) as a reference, given by:

$$EOT = \frac{3.9}{κ} \cdot d \qquad ( Eqn . 2 )$$

where d represents the physical thickness of the capacitor dielectric.

As DRAM technologies scale below the 40 nm technology node, manufacturers must reduce the EOT of the high-k dielectric films in MIM capacitors in order to increase charge storage capacity. The goal is to utilize dielectric materials that exhibit an EOT of less than about 0.8 nm while maintaining a physical thickness of about 5-20 nm.

There is a need to develop processes that allow the formation of a metal oxide-based electrode material that can serve as a template for the high-k phases of subsequently deposited dielectric layers, that contributes to lower leakage current, and has low resistivity, which contributes to higher device speed and lower power usage.

### SUMMARY

The following summary of the disclosure is included in order to provide a basic understanding of some aspects and features of the invention. This summary is not an extensive overview of the invention and as such it is not intended to particularly identify key or critical elements of the invention or to delineate the scope of the invention. Its sole purpose is to present some concepts of the invention in a simplified form as a prelude to the more detailed description that is presented below.

In some embodiments, a base bottom electrode layer includes a conductive metal nitride material. In some embodiments, the conductive metal nitride material includes one of titanium nitride, titanium aluminum nitride, titanium silicon nitride, tantalum nitride, tantalum aluminum nitride, or tantalum silicon nitride. In some embodiments, a second bottom electrode layer includes a conductive metal oxide material. In some embodiments, the conductive metal oxide material includes molybdenum oxide. In some embodiments, molybdenum nitride or a molybdenum oxy-nitride layer is deposited above a dielectric layer. In some embodiments, a base top electrode layer includes a conductive metal nitride material. In some embodiments, the conductive metal nitride material includes one of titanium nitride, titanium aluminum nitride, titanium silicon nitride, tantalum nitride, tantalum aluminum nitride, or tantalum silicon nitride.

### BRIEF DESCRIPTION OF THE DRAWINGS

To facilitate understanding, identical reference numerals have been used, where possible, to designate identical elements that are common to the figures. The drawings are not to scale and the relative dimensions of various elements in the drawings are depicted schematically and not necessarily to scale.

The techniques of the present invention can readily be understood by considering the following detailed description in conjunction with the accompanying drawings, in which:

FIG. 1 illustrates a flow chart illustrating building blocks and sequences for fabricating a DRAM capacitor stack in accordance with some embodiments.

FIG. 2 illustrates a simplified cross-sectional view of DRAM capacitor building blocks for manufacturing stacks in accordance with some embodiments.

FIG. 3 illustrates a simplified cross-sectional view of DRAM memory cell building blocks for manufacturing stacks in accordance with some embodiments.

### DETAILED DESCRIPTION

A detailed description of one or more embodiments is provided below along with accompanying figures. The detailed description is provided in connection with such embodiments, but is not limited to any particular example. The scope is limited only by the claims and numerous alternatives, modifications, and equivalents are encompassed. Numerous specific details are set forth in the following description in order to provide a thorough understanding. These details are provided for the purpose of example and the described techniques may be practiced according to the claims without some or all of these specific details. For the purpose of clarity, technical material that is known in the technical fields related to the embodiments has not been described in detail to avoid unnecessarily obscuring the description.

It must be noted that as used herein and in the claims, the singular forms “a,” “an,” and “the” include plural referents unless the context clearly dictates otherwise. Thus, for example, reference to “a layer” includes two or more layers, and so forth.

Where a range of values is provided, it is understood that each intervening value, to the tenth of the unit of the lower limit unless the context clearly dictates otherwise, between the upper and lower limit of that range, and any other stated or intervening value in that stated range, is encompassed within the invention. The upper and lower limits of these smaller ranges may independently be included in the smaller ranges, and are also encompassed within the invention, subject to any specifically excluded limit in the stated range. Where the stated range includes one or both of the limits, ranges excluding either or both of those included limits are also included in the invention. Where the modifier “about” or “approximately” is used, the stated quantity can vary by up to 10%.

As used herein, the term “substantially” generally refers to ±5% of a stated value.

The term “horizontal” as used herein will be understood to be defined as a plane parallel to the plane or surface of the substrate, regardless of the orientation of the substrate. The term “vertical” will refer to a direction perpendicular to the horizontal as previously defined. Terms such as “above”, “below”, “bottom”, “top”, “side” (e.g. sidewall), “higher”, “lower”, “upper”, “over”, and “under”, are defined with respect to the horizontal plane. The term “on” means there is direct contact between the elements. The term “above” will allow for intervening elements.

As used herein, a material (e.g. a dielectric material or an electrode material) will be considered to be “crystalline” if it exhibits greater than or equal to 30% crystallinity as measured by a technique such as x-ray diffraction (XRD).

The term “substrate” as used herein may refer to any workpiece on which formation or treatment of material layers is desired. Non-limiting examples include silicon, germanium, silica, sapphire, zinc oxide, silicon carbide, aluminum nitride, gallium nitride, Spinel, silicon on oxide, silicon carbide on oxide, glass, gallium nitride, indium nitride, aluminum nitride, glasses, combinations or alloys thereof, and other solid materials.

As used herein, the notation “Mo—O” and “MoO” and “MoOₓ” will be understood to be equivalent and will be used interchangeably and will be understood to include a material containing these elements in any ratio. Where a specific composition is discussed, the atomic concentrations (or ranges) will be provided. The notation is extendable to other materials and other elemental combinations (e.g. Mo—O—N, MoON, MoONₓ, etc.) discussed herein.

As used herein, the terms “film” and “layer” will be understood to represent a portion of a stack. They will be understood to cover both a single layer as well as a multilayered structure (i.e. a nanolaminate). As used herein, these terms will be used synonymously and will be considered equivalent.

As used herein, the term “between” (when used with a range of values) will be understood to mean that both boundary values and any value between the boundaries can be within the scope of the range.

As used herein, the terms “first,” “second,” and other ordinals will be understood to provide differentiation only, rather than imposing any specific spatial or temporal order.

As used herein, the term “oxide” (of an element) will be understood to include additional components besides the element and oxygen, including but not limited to a dopant or alloy.

As used herein, the term “nitride” (of an element) will be understood to include additional components besides the element and nitrogen, including but not limited to a dopant or alloy.

Dopants can be added to the dielectric material to increase the k-value and/or decrease the leakage current. As used herein, the dopant may be electrically active or not electrically active. The definition excludes residues and impurities such as carbon, etc. that may be present in the material due to inefficiencies of the process or impurities in the precursor materials. The concentration of the dopant is one factor that affects the crystallinity of the dielectric material. Other factors that affect the crystallinity of the dielectric material comprise annealing time, annealing temperature, film thickness, etc. Generally, as the concentration of the dopant is increased, the crystallization temperature of the dielectric material increases.

The term “nanolaminate”, as used herein, will be understood to be defined as a material or layer that is formed from the deposition of a plurality of sub-layers. Typically, the sub-layers include different materials and the different sub-layers are alternated in a predetermined ratio of thicknesses and/or compositions.

As used herein, the term “flash layer” will be understood to describe an additional layer inserted between the first (e.g. bottom) electrode layer and the dielectric layer.

As used herein, the term “capping layer” will be understood to describe an additional layer inserted between the second (e.g. top) electrode layer and the dielectric layer.

As used herein, the term “blocking layer” will be understood to describe an additional generic layer inserted either between the first (e.g. bottom) electrode layer and the dielectric layer, between the second (e.g. top) electrode layer and the dielectric layer, or both. As defined above, both “flash layers” and “capping layers” are examples of the more general “blocking layer”.

As used herein, the term “inert gas” will be understood to include noble gases (He, Ne, Ar, Kr, Xe) and, unless the text or context excludes it (e.g., by describing nitride formation as undesirable), nitrogen (N₂).

As used herein, the term “monolayer” will be understood to include a single layer of atoms or molecules covering a surface, with substantially all available bonding sites satisfied and substantially all individual members of the adsorbed species in direct physical contact with the underlying surface.

As used herein, the term “sub-monolayer” or “pre-wetting layer” will be understood to include a partial or incomplete monolayer; maximum thickness is one atom or molecule, but not all available bonding sites on the surface are covered, so that the average thickness is less than one atom or molecule.

As used herein, the term “Surface” will be understood to describe the boundary between the ambient environment and a feature of the substrate.

Those skilled in the art will appreciate that each of the layers discussed herein and used in the DRAM MIM capacitor may be formed using any common formation technique such as atomic layer deposition (ALD), plasma enhanced atomic layer deposition (PE-ALD), atomic vapor deposition (AVD), ultraviolet assisted atomic layer deposition (UV-ALD), chemical vapor deposition (CVD), plasma enhanced chemical vapor deposition (PECVD), or physical vapor deposition (PVD). Generally, because of the complex morphology of the DRAM capacitor structure, ALD, PE-ALD, AVD, or CVD are preferred methods of formation. However, any of these techniques are suitable for forming each of the various layers discussed herein. Those skilled in the art will appreciate that the teachings described herein are not limited by the technology used for the deposition process.

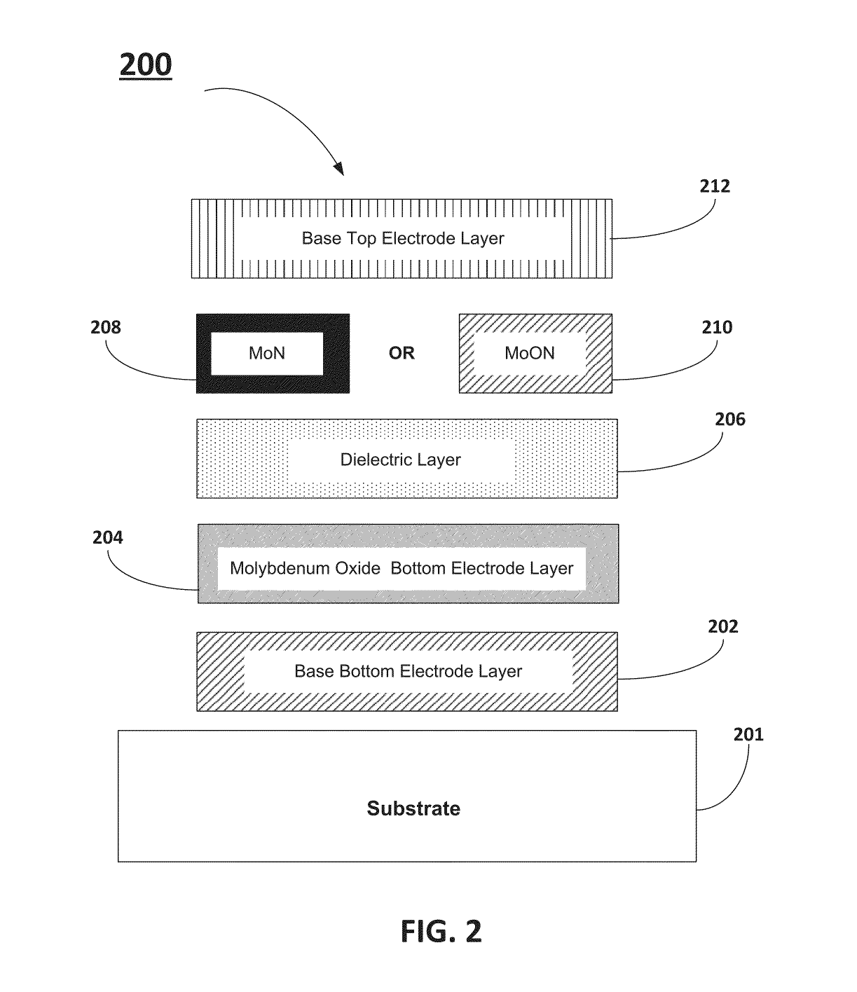

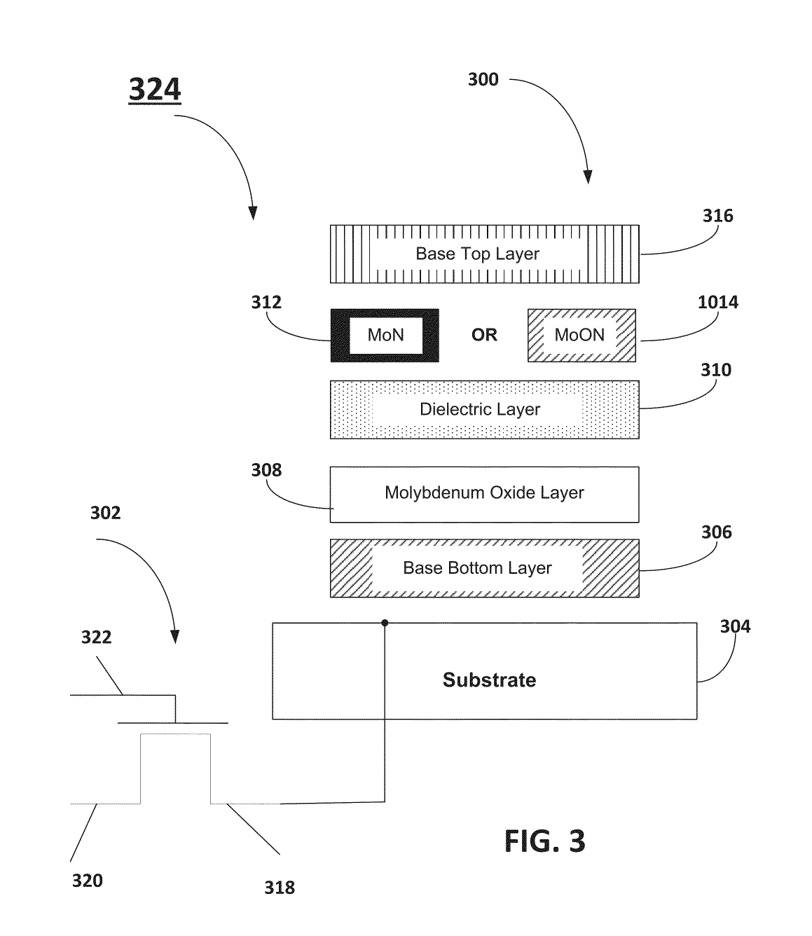

In FIGS. 2 and 3, a capacitor stack is illustrated using a simple planar structure. Those skilled in the art will appreciate that the description and teachings herein can be readily applied to any simple or complex capacitor morphology. The drawings are for illustrative purposes only and do not limit the application of the present disclosure.

One class of high-k dielectric materials possessing the characteristics required for implementation in advanced DRAM capacitors includes high-k metal oxide materials. Titanium oxide and zirconium oxide are two metal oxide dielectric materials which display significant promise in terms of serving as high-k dielectric materials for implementation in DRAM capacitors. Other metal oxide high-k dielectric materials that have attracted attention include aluminum oxide, barium-strontium-titanate (BST), erbium oxide, hafnium oxide, hafnium silicate, lanthanum oxide, niobium oxide, lead-zirconium-titanate (PZT), a bilayer of silicon oxide and silicon nitride, silicon oxy-nitride, strontium titanate (STO), tantalum oxide, titanium oxide, zirconium oxide, etc.

The dielectric constant of a dielectric material may be dependent upon the crystalline phase(s) of the material. For example, in the case of titanium oxide (specifically TiO₂), the anatase crystalline phase of TiO₂ has a dielectric constant of approximately 40, while the rutile crystalline phase of TiO₂ can have a dielectric constant of approximately >80. Due to the higher k-value of the rutile-phase, it is desirable to produce TiO₂ based DRAM capacitors with the TiO₂ in the rutile-phase. The relative amounts of the anatase phase and the rutile phase can be determined from x-ray diffraction (XRD). From Eqn. 1 above, a TiO₂ material in the rutile-phase could be physically thicker and maintain the desired capacitance. The increased physical thickness is important for lowering the leakage current of the capacitor. The anatase phase will transition to the rutile phase at high temperatures (>8000). However, high temperature processes are undesirable in the manufacture of DRAM devices. Similarly, the cubic and tetragonal phases of ZrO₂ have a higher-k value than the monoclinic phase. So, it is desirable to produce ZrO₂ based DRAM capacitors with the ZrO₂ in the cubic or tetragonal phase, with the tetragonal phase being most preferred.

The crystal phase of an adjacent material can be used to influence the growth of a specific crystal phase of a material if their crystal structures are similar and their lattice constants are similar. This technique is well known in technologies such as epitaxial growth. The same concepts have been extended to the growth of thin films where the adjacent material can be used as a “template” to encourage the growth of a desired crystalline phase over other competing crystal phases.

Generally, as the dielectric constant of a material increases, the band gap of the material decreases. This leads to high leakage current in the device. As a result, without the utilization of countervailing measures, capacitor stacks implementing high-k dielectric materials may experience large leakage currents. High work function electrodes (e.g., electrodes having a work function of greater than 5.0 eV) may be utilized in order to counter the effects of implementing a reduced band gap high-k dielectric material within the DRAM capacitor. Metals, such as platinum, gold, ruthenium, and ruthenium oxide are examples of high work function electrode materials suitable for inhibiting device leakage in a DRAM capacitor having a high-k dielectric material. The noble metal systems, however, are prohibitively expensive when employed in a mass production context. Moreover, electrodes fabricated from noble metals often suffer from poor manufacturing qualities, such as surface roughness and poor adhesion, and form a contamination risk in the fab.

Additionally, DRAM capacitor stacks may undergo various refinement process steps after fabrication. These refinement processes may include post-fabrication chemical and thermal processing (i.e., oxidation or reduction). For instance, after initial DRAM capacitor stack fabrication, a number of high temperature (up to about 600 C) processes may be applied to complete the device fabrication. During these subsequent process steps, the DRAM capacitor materials must remain chemically, physically, and structurally stable. They must maintain the structural, compositional, physical, and electrical properties that have been developed. Furthermore, they should not undergo significant interaction or reaction which may degrade the performance of the DRAM capacitor.

Conductive metal oxides, conductive metal silicides, conductive metal carbides, conductive metal nitrides, or combinations thereof comprise other classes of materials that may be suitable as DRAM capacitor electrodes. Generally, transition metals and their conductive binary compounds form good candidates as electrode materials. The transition metals exist in several oxidation states. Therefore, a wide variety of compounds are possible. Conductive metal nitrides such as titanium nitride, tantalum nitride, tungsten nitride, etc. have attracted interest as DRAM capacitor electrodes with titanium nitride being the most popular. Different compounds may have different crystal structures, electrical properties, etc. It is important to utilize the proper compound for the desired application.

In one example, molybdenum has several binary oxides of which MoO₂ and MoO₃ are two examples. These two oxides of molybdenum have different properties. MoO₂ is conductive and has shown great promise as an electrode material in DRAM capacitors. MoO₂ has a distorted rutile crystal structure and can serve as an acceptable template to promote the deposition of the rutile-phase of titanium oxide as discussed above. MoO₂ also has a high work function (can be >5.0 eV depending on process history) which helps to minimize the leakage current of the DRAM device. However, oxygen-rich phases (MoO₂₊ₓ) of MoO₂ degrade the performance of the MoO₂ electrode material because they act more like insulators and have crystal structures that do not promote the formation of the rutile-phase of titanium oxide. For example, MoO₃ (the most oxygen-rich phase) is a dielectric material and has an orthorhombic crystal structure.

Generally, a deposited thin film may be amorphous, crystalline, or a mixture thereof. Furthermore, several different crystalline phases may exist. Therefore, processes (both deposition and post-treatment) must be developed to maximize the formation of crystalline MoO₂ and to minimize the presence of MoO₂₊ₓ phases. Deposition processes and post-treatment processes in an inert or reducing atmosphere have been developed that allow crystalline MoO₂ to be used as the first electrode material (i.e. bottom electrode) in MIM DRAM capacitors with TiO₂ or doped-TiO₂ high-k dielectric materials. Examples of the post-treatment process are further described in U.S. application Ser. No. 13/084,666 filed on Apr. 12, 2011, which is incorporated herein by reference for all purposes. Other conductive metal oxides that may be used as a template for the rutile phase of TiO₂ include the conductive compounds of chromium oxide, cobalt oxide, iridium oxide, manganese oxide, nickel oxide, ruthenium oxide, tin oxide, or tungsten oxide.

Molybdenum nitride and molybdenum oxy-nitride are also candidates as electrode materials for use in DRAM capacitors. These materials have a work function in the range of 4.8 to 6.0 eV, depending on the composition and deposition parameters. These materials have low resistivity and do not require annealing treatments to convert the deposited film into a desirable crystalline phase. This last benefit makes them especially attractive as second (e.g. top) electrode materials where it may not be attractive to subject the entire capacitor stack to an additional annealing step. The implementation of these materials into a DRAM capacitor stack will be discussed below.

In some embodiments, the electrode layer(s) are formed from two or more materials. As an example, a molybdenum oxide layer may be used as a template for the rutile phase of a titanium oxide layer that is to be subsequently deposited. To lower the overall resistivity of the electrode layer, this molybdenum oxide layer can be paired with a more highly conductive layer. Examples of the more highly conductive layer include metals, other conductive metal oxides, conductive metal silicides, conductive metal nitrides, and combinations thereof. Specific examples of a metal nitride include titanium nitride, tantalum nitride. As used herein, this highly conductive layer will be designated as a “base bottom electrode layer” or a “base top electrode layer”, depending on where it is used in the DRAM stack.

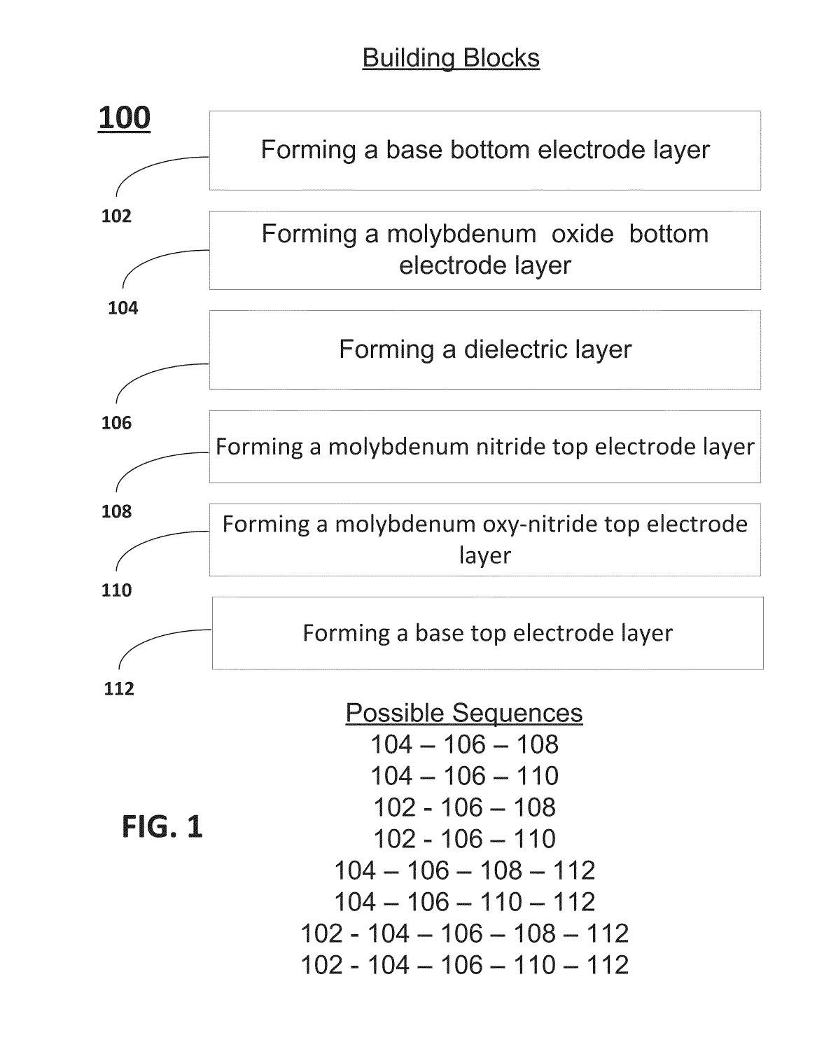

FIG. 1 describes various building block steps, 100, for fabricating a DRAM capacitor stack. FIG. 1 also illustrates a number of possible sequences for arranging the various steps to form a capacitor stack. One step, 102, includes forming a base bottom electrode layer above a substrate. Examples of suitable base bottom electrode materials include metals, conductive metal oxides, conductive metal silicides, conductive metal nitrides, and combinations thereof. Two particularly interesting classes of materials are the conductive metal oxides and the conductive metal nitrides. The purpose of the base bottom electrode layer is to serve as a primary conductor. Examples of suitable materials for the base bottom electrode layer include titanium nitride, titanium aluminum nitride, titanium silicon nitride, tantalum nitride, tantalum aluminum nitride, tantalum silicon nitride, or combinations thereof.

Another step, 104, includes forming a molybdenum oxide bottom electrode layer. The molybdenum oxide bottom electrode layer may be implemented alone or paired with the base bottom electrode layer as discussed previously. The purpose of the molybdenum oxide bottom electrode layer is to promote a desired crystallographic structure and orientation of a subsequently deposited dielectric layer. As discussed previously, the k-value of a dielectric material may vary as a function of its crystallographic structure and orientation. Although molybdenum oxide is used as the example for the bottom electrode layer, those skilled in the art will understand that other metal oxides that can serve as a template for the rutile phase of the titanium oxide dielectric layer can also be used. Examples of these other metal oxides include iridium oxide and ruthenium oxide.

The base bottom electrode layer and/or the molybdenum oxide bottom electrode layer can then be subjected to an annealing process (not shown). The annealing step serves to crystallize the molybdenum oxide bottom electrode layer.

Another step, 106, includes forming a dielectric layer above the molybdenum oxide bottom electrode layer. Optionally, the dielectric layer can then be subjected to a post dielectric anneal (PDA) treatment (not shown). The PDA step serves to crystallize the dielectric material and fill oxygen vacancies.

Another step, 108, includes forming a molybdenum nitride top electrode layer above the dielectric layer to form a capacitor stack. As discussed previously, the molybdenum nitride layer has the advantages of low resistivity, high work function, and does not require an anneal treatment to induce the proper crystalline phase.

Another step, 110, includes forming a molybdenum oxy-nitride top electrode layer above the dielectric layer to form a capacitor stack. As discussed previously, the molybdenum oxy-nitride layer has the advantages of low resistivity, high work function, and does not require an anneal treatment to induce the proper crystalline phase.

Another step, 112, includes forming a base top electrode layer above a substrate. Examples of suitable base top electrode materials include metals, conductive metal oxides, conductive metal silicides, conductive metal nitrides, and combinations thereof. Two particularly interesting classes of materials are the conductive metal oxides and the conductive metal nitrides. The purpose of the base top electrode layer is to serve as a primary conductor. Examples of suitable materials for the base top electrode layer include titanium nitride, titanium aluminum nitride, titanium silicon nitride, tantalum nitride, tantalum aluminum nitride, tantalum silicon nitride, or combinations thereof.

Optionally, the capacitor stack can then be subjected to a post metallization anneal (PMA) treatment process (not shown). In some embodiments, the PMA treatment is performed soon (i.e. before further processing steps) after the forming of the top electrode layer(s). The PMA treatments are typically performed in an inert gas (e.g. nitrogen or argon) or in a dilute oxygen atmosphere (e.g. less than about 10% oxygen in nitrogen or argon). Preferably, the PMA treatments are performed in an inert gas. Examples of the PDA and PMA treatments are further described in U.S. patent application Ser. No. 13/159,842, filed on Jun. 14, 2011, (US Publication 2012/0322220), which is herein incorporated by reference for all purposes.

The building block steps described above can be combined in a number of ways to form various MIM stacks. Some of the sequences are listed in FIG. 1.

In some embodiments, building block steps 104, 106, and 108 can be combined to form a stack including: substrate/molybdenum oxide electrode layer/dielectric layer/molybdenum nitride electrode layer (one example—substrate/MoO₂/Al-doped TiO₂/MoN). Various intermediate anneal treatments may be employed as discussed previously. Various dielectric layers may be used as listed above.

In some embodiments, building block steps 104, 106, and 110 can be combined to form a stack including: substrate/molybdenum oxide electrode layer/dielectric layer/molybdenum oxy-nitride electrode layer (one example—substrate/MoO₂/Al-doped TiO₂/MoON). Various intermediate anneal treatments may be employed as discussed previously. Various dielectric layers may be used as listed above.

In some embodiments, building block steps 102, 106, and 108 can be combined to form a stack including: substrate/base bottom electrode layer/dielectric layer/molybdenum nitride electrode layer (one example—substrate/TiN/Al-doped TiO₂/MoN). Various base bottom electrode layers may be used as listed above. Various intermediate anneal treatments may be employed as discussed previously. Various dielectric layers may be used as listed above.

In some embodiments, building block steps 102, 106, and 110 can be combined to form a stack including: substrate/base bottom electrode layer/dielectric layer/molybdenum oxy-nitride electrode layer (one example—substrate/TiN/Al-doped TiO₂/MoON). Various base bottom electrode layers may be used as listed above. Various intermediate anneal treatments may be employed as discussed previously. Various dielectric layers may be used as listed above.

In some embodiments, building block steps 104, 106, 108, and 112 can be combined to form a stack including: substrate/molybdenum oxide electrode layer/dielectric layer/molybdenum nitride electrode layer/base top electrode layer (one example—substrate/MoO₂/Al-doped TiO₂/MoN/TiN). Various intermediate anneal treatments may be employed as discussed previously. Various dielectric layers may be used as listed above. Various base top electrode layers may be used as listed above.

In some embodiments, building block steps 104, 106, 110, and 112 can be combined to form a stack including: substrate/molybdenum oxide electrode layer/dielectric layer/molybdenum oxy-nitride electrode layer/base top electrode layer (one example—substrate/MoO₂/Al-doped TiO₂/MoON/TiN). Various intermediate anneal treatments may be employed as discussed previously. Various dielectric layers may be used as listed above. Various base top electrode layers may be used as listed above.

In some embodiments, building block steps 102, 104, 106, 108, and 112 can be combined to form a stack including: substrate/base bottom electrode layer/molybdenum oxide electrode layer/dielectric layer/molybdenum nitride electrode layer/base top electrode layer (one example—substrate/TiN/MoO₂/Al-doped TiO₂/MoN/TiN). Various intermediate anneal treatments may be employed as discussed previously. Various base bottom electrode layers may be used as listed above. Various dielectric layers may be used as listed above. Various base top electrode layers may be used as listed above.

In some embodiments, building block steps 102, 104, 106, 110, and 112 can be combined to form a stack including: substrate/base bottom electrode layer/molybdenum oxide electrode layer/dielectric layer/molybdenum oxy-nitride electrode layer/base top electrode layer (one example—substrate/TiN/MoO₂/Al-doped TiO₂/MoON/TiN). Various intermediate anneal treatments may be employed as discussed previously. Various base bottom electrode layers may be used as listed above. Various dielectric layers may be used as listed above. Various base top electrode layers may be used as listed above.

FIG. 2 describes various building block layers, 100, for fabricating a DRAM capacitor stack. FIG. 2 also illustrates a number of possible sequences for arranging the various layers to form a capacitor stack. One layer, 102, includes a base bottom electrode layer formed above a substrate. Examples of suitable base bottom electrode materials include metals, conductive metal oxides, conductive metal silicides, conductive metal nitrides, and combinations thereof. Two particularly interesting classes of materials are the conductive metal oxides and the conductive metal nitrides. The purpose of the base bottom electrode layer is to serve as a primary conductor. Examples of suitable materials for the base bottom electrode layer include titanium nitride, titanium aluminum nitride, titanium silicon nitride, tantalum nitride, tantalum aluminum nitride, tantalum silicon nitride, or combinations thereof.

Another layer, 204, includes a molybdenum oxide bottom electrode layer. The molybdenum oxide bottom electrode layer may be implemented alone or paired with the base bottom electrode layer as discussed previously. The purpose of the molybdenum oxide bottom electrode layer is to promote a desired crystallographic structure and orientation of a subsequently deposited dielectric layer. As discussed previously, the k-value of a dielectric material may vary as a function of its crystallographic structure and orientation.

Another layer, 206, includes a dielectric layer formed above the bottom electrode layer(s). A wide variety of dielectric materials have been targeted for use in DRAM capacitors. Examples of suitable dielectric materials include aluminum oxide, barium-strontium-titanate (BST), erbium oxide, hafnium oxide, lanthanum oxide, niobium oxide, lead-zirconium-titanate (PZT), a bilayer of silicon oxide and silicon nitride, silicon oxy-nitride, strontium titanate (STO), tantalum oxide, titanium oxide, zirconium oxide, or doped versions of the same. These dielectric materials may be formed as a single layer or may be formed as a hybrid or nanolaminate structure. In some embodiments, the dielectric material is titanium oxide. In some embodiments, the dielectric material is doped titanium oxide. Typical dopants for titanium oxide include Al, Ce, Co, Er, Ga, Gd, Ge, Hf, In, La, Lu, Mg, Mn, Nd, Pr, Sc, Si, Sn, Sr, Y, Zr, or combinations thereof.

Another layer, 208, includes a molybdenum nitride top electrode layer formed above the dielectric layer to form a capacitor stack. As discussed previously, the molybdenum nitride layer has the advantages of low resistivity, high work function, and does not require an anneal treatment to induce the proper crystalline phase.

Another layer, 210, includes a molybdenum oxy-nitride top electrode layer formed above the dielectric layer to form a capacitor stack. As discussed previously, the molybdenum oxy-nitride layer has the advantages of low resistivity, high work function, and does not require an anneal treatment to induce the proper crystalline phase.

Another layer, 212, includes a base top electrode layer formed above a substrate. Examples of suitable base top electrode materials include metals, conductive metal oxides, conductive metal silicides, conductive metal nitrides, and combinations thereof. Two particularly interesting classes of materials are the conductive metal oxides and the conductive metal nitrides. The purpose of the base top electrode layer is to serve as a primary conductor. Examples of suitable materials for the base top electrode layer include titanium nitride, titanium aluminum nitride, titanium silicon nitride, tantalum nitride, tantalum aluminum nitride, tantalum silicon nitride, or combinations thereof.

Optionally, the capacitor stack can then be subjected to a post metallization anneal (PMA) treatment process (not shown). In some embodiments, the PMA treatment is performed soon (i.e. before further processing steps) after the forming of the top electrode layer(s). The PMA treatments are typically performed in an inert gas (e.g. nitrogen or argon) or in a dilute oxygen atmosphere (e.g. less than about 10% oxygen in nitrogen or argon). Preferably, the PMA treatments are performed in an inert gas.

The building block layers described above can be combined in a number of ways to form various MIM stacks.

In some embodiments, building block layers 204, 206, and 208 can be combined to form a stack including: substrate/molybdenum oxide electrode layer/dielectric layer/molybdenum nitride electrode layer (one example—substrate/MoO₂/Al-doped TiO₂/MoN). Various intermediate anneal treatments may be employed as discussed previously. Various dielectric layers may be used as listed above.

In some embodiments, building block layers 204, 206, and 210 can be combined to form a stack including: substrate/molybdenum oxide electrode layer/dielectric layer/molybdenum oxy-nitride electrode layer (one example—substrate/MoO₂/Al-doped TiO₂/MoON). Various intermediate anneal treatments may be employed as discussed previously. Various dielectric layers may be used as listed above.

In some embodiments, building block layers 202, 206, and 208 can be combined to form a stack including: substrate/base bottom electrode layer/dielectric layer/molybdenum nitride electrode layer (one example—substrate/TiN/Al-doped TiO₂/MoN). Various base bottom electrode layers may be used as listed above. Various intermediate anneal treatments may be employed as discussed previously. Various dielectric layers may be used as listed above.

In some embodiments, building block layers 202, 206, and 210 can be combined to form a stack including: substrate/base bottom electrode layer/dielectric layer/molybdenum oxy-nitride electrode layer (one example—substrate/TiN/Al-doped TiO₂/MoON). Various base bottom electrode layers may be used as listed above. Various intermediate anneal treatments may be employed as discussed previously. Various dielectric layers may be used as listed above.

In some embodiments, building block layers 204, 206, 208, and 212 can be combined to form a stack including: substrate/molybdenum oxide electrode layer/dielectric layer/molybdenum nitride electrode layer/base top electrode layer (one example—substrate/MoO₂/Al-doped TiO₂/MoN/TiN). Various intermediate anneal treatments may be employed as discussed previously. Various dielectric layers may be used as listed above. Various base top electrode layers may be used as listed above.

In some embodiments, building block layers 204, 206, 210, and 212 can be combined to form a stack including: substrate/molybdenum oxide electrode layer/dielectric layer/molybdenum oxy-nitride electrode layer/base top electrode layer (one example—substrate/MoO₂/Al-doped TiO₂/MoON/TiN). Various intermediate anneal treatments may be employed as discussed previously. Various dielectric layers may be used as listed above. Various base top electrode layers may be used as listed above.

In some embodiments, building block layers 202, 204, 206, 208, and 212 can be combined to form a stack including: substrate/base bottom electrode layer/molybdenum oxide electrode layer/dielectric layer/molybdenum nitride electrode layer/base top electrode layer (one example—substrate/TiN/MoO₂/Al-doped TiO₂/MoN/TiN). Various intermediate anneal treatments may be employed as discussed previously. Various base bottom electrode layers may be used as listed above. Various dielectric layers may be used as listed above. Various base top electrode layers may be used as listed above.

In some embodiments, building block layers 202, 204, 206, 210, and 212 can be combined to form a stack including: substrate/base bottom electrode layer/molybdenum oxide electrode layer/dielectric layer/molybdenum oxy-nitride electrode layer/base top electrode layer (one example—substrate/TiN/MoO₂/Al-doped TiO₂/MoON/TiN). Various intermediate anneal treatments may be employed as discussed previously. Various base bottom electrode layers may be used as listed above. Various dielectric layers may be used as listed above. Various base top electrode layers may be used as listed above.

In some embodiments, a DRAM MIM capacitor stack includes a bottom electrode layer having a total thickness between about 4 nm and about 10 nm (e.g. between 4 nm and 6 nm). As discussed previously, the bottom electrode layer may include a layer of molybdenum oxide or may include a multi-layer of molybdenum oxide and a base bottom electrode layer (e.g. a conductive metal nitride such as titanium nitride). Other examples of suitable conductive metal nitrides include titanium aluminum nitride, titanium silicon nitride, tantalum nitride, tantalum aluminum nitride, or tantalum silicon nitride, nickel nitride, tungsten nitride, vanadium nitride, molybdenum nitride, and cobalt nitride, or combinations thereof. The bottom electrode layer(s) may be formed at a process temperature between about 100 C and 600 C using an ALD or CVD process technology. Optionally, the substrate with the first bottom electrode layer and the second bottom electrode layer is then annealed in an inert (e.g. argon or nitrogen) or a reducing atmosphere for between about 1 millisecond and about 60 minutes. In some embodiments, the reducing atmosphere includes between about 1% and about 20% H₂ in N₂ and advantageously between about 5% and about 10% H₂ in N₂ between 400 and 520 C.

A dielectric layer is then formed on the annealed bottom electrode layer(s). A wide variety of dielectric materials have been targeted for use in DRAM capacitors. Examples of suitable dielectric materials include aluminum oxide, barium-strontium-titanate (BST), erbium oxide, hafnium oxide, lanthanum oxide, niobium oxide, lead-zirconium-titanate (PZT), a bilayer of silicon oxide and silicon nitride, silicon oxy-nitride, strontium titanate (STO), tantalum oxide, titanium oxide, zirconium oxide, or doped versions of the same. These dielectric materials may be formed as a single layer or may be formed as a hybrid or nanolaminate structure. Typical dopants for titanium oxide include Al, Ce, Co, Er, Ga, Gd, Ge, Hf, In, La, Lu, Mg, Mn, Nd, Pr, Sc, Si, Sn, Sr, Y, Zr, or combinations thereof. Typically, the dielectric layer is subjected to a PDA treatment before the formation of the top electrode layer(s) as discussed previously. A dielectric material of interest is titanium oxide doped with aluminum (e.g. as aluminum oxide) to between about 1 atomic % and about 15 atomic % Al as calculated by (Al/(Al+Ti)).

In a specific example, the dielectric layer comprises between about 3 nm to about 9 nm (e.g. between 6 nm and 7 nm) of TiO₂. Generally, the TiO₂ dielectric layer may either be a single film or may comprise a nanolaminate. Advantageously, the TiO₂ material is doped with Al at a concentration between about 1 atomic % and about 15 atomic % Al as calculated by (Al(Al+Ti)). The TiO₂ dielectric layer is formed at a process temperature between about 200 C and 350 C using an ALD process technology. The substrate with the bottom electrode layer(s) and dielectric layer is then annealed in an oxidizing atmosphere comprising between about 0% O₂ to about 100% O₂ in N₂ and advantageously between about 0% O₂ to about 20% O₂ in N₂ at temperatures between about 400 C to about 600 C for between about 1 millisecond to about 60 minutes.

In the next step, a top electrode layer having a total thickness between about 2 nm and about 6 nm (e.g. between 2 nm and 4 nm). As discussed previously, the top electrode layer may include a layer of molybdenum nitride (or molybdenum oxy-nitride) or may include a multi-layer of molybdenum nitride (or molybdenum oxy-nitride) and a base top electrode layer (e.g. a conductive metal nitride such as titanium nitride). The base top electrode layer(s) may include one of, metals, metal alloys, conductive metal oxides, conductive metal nitrides, conductive metal silicides, or combinations thereof, etc. In some embodiments, the top electrode layer(s) include a conductive metal nitride. Examples of suitable conductive metal nitrides include titanium nitride, titanium aluminum nitride, titanium silicon nitride, tantalum nitride, tantalum aluminum nitride, or tantalum silicon nitride, nickel nitride, tungsten nitride, vanadium nitride, molybdenum nitride, and cobalt nitride, or combinations thereof. The top electrode layer(s) may be formed at a process temperature between about 100 C and 600 C using an ALD or CVD process technology. The capacitor stack may receive a PMA treatment as discussed previously.

An example of a specific application of some embodiments is in the fabrication of capacitors used in the memory cells in DRAM devices. DRAM memory cells effectively use a capacitor to store charge for a period of time, with the charge being electronically “read” to determine whether a logical “one” or “zero” has been stored in the associated cell. Conventionally, a cell transistor is used to access the cell. The cell transistor is turned “on” in order to store data on each associated capacitor and is otherwise turned “off” to isolate the capacitor and preserve its charge. More complex DRAM cell structures exist, but this basic DRAM structure will be used for illustrating the application of this disclosure to capacitor manufacturing and to DRAM manufacturing. FIG. 3 is used to illustrate one DRAM cell, 324, manufactured using a dielectric structure as discussed previously. The cell, 324, is illustrated schematically to include two principal components, a cell capacitor, 300, and a cell transistor, 302. The cell transistor is usually constituted by a MOS transistor having a gate, 322, source, 318, and drain, 320. The gate is usually connected to a word line and one of the source or drain is connected to a bit line. The cell capacitor has a lower or storage electrode, 306+308, and an upper or plate electrode, 314+316. The storage electrode is connected to the other of the source or drain and the plate electrode is connected to a reference potential conductor. The cell transistor is, when selected, turned “on” by an active level of the word line to read or write data from or into the cell capacitor via the bit line.

FIG. 3 describes various building block layers for fabricating a DRAM capacitor stack. FIG. 3 also illustrates a number of possible sequences for arranging the various layers to form a capacitor stack. As was described previously, the cell capacitor, 300, may include building blocks such as a base bottom electrode layer, 306 and/or a molybdenum oxide bottom electrode layer 308, formed above substrate, 304. The bottom electrode layer, (306 and/or 308), is connected to the source or drain of the cell transistor, 302. For illustrative purposes, the bottom electrode has been connected to the source, 318, in this example. Bottom electrode layer, (306 and/or 308), can include one of metals, conductive metal oxides, conductive metal nitrides, conductive metal silicides, and combinations thereof. In some embodiments, the bottom electrode material includes a layer of molybdenum oxide or may include a multi-layer of molybdenum oxide and a base bottom electrode layer (e.g. a conductive metal nitride such as titanium nitride). Other examples of suitable conductive metal nitrides include titanium aluminum nitride, titanium silicon nitride, tantalum nitride, tantalum aluminum nitride, or tantalum silicon nitride, nickel nitride, tungsten nitride, vanadium nitride, molybdenum nitride, and cobalt nitride, or combinations thereof. In some embodiments, base first bottom electrode material includes titanium nitride or tantalum nitride.

A second bottom electrode layer building block, 308, may be formed above the base bottom electrode layer. Examples of suitable second bottom electrode materials include metals, conductive metal oxides, conductive metal silicides, conductive metal nitrides, and combinations thereof. A particularly interesting class of materials is the conductive metal oxides. Examples of suitable metal oxide materials for the second bottom electrode layer include molybdenum oxide, chromium oxide, cobalt oxide, iridium oxide, manganese oxide, nickel oxide, ruthenium oxide, tin oxide, or tungsten oxide. In some embodiments, second bottom electrode layer includes molybdenum oxide. As discussed previously, first bottom electrode layer, 306, and second bottom electrode layer, 308, may be subjected to an anneal before the formation of the dielectric layer if the second bottom electrode layer is a conductive metal oxide (e.g. molybdenum oxide).

Crystalline, doped, high-k dielectric building block layer, 310, is formed above the bottom electrode layer. Examples of suitable dielectric materials include aluminum oxide, barium-strontium-titanate (BST), erbium oxide, hafnium oxide, lanthanum oxide, niobium oxide, lead-zirconium-titanate (PZT), a bilayer of silicon oxide and silicon nitride, silicon oxy-nitride, strontium titanate (STO), tantalum oxide, titanium oxide, zirconium oxide, or doped versions of the same. These dielectric materials may be formed as a single layer or may be formed as a hybrid or nanolaminate structure. In some embodiments, the dielectric material is titanium oxide. In some embodiments, the dielectric material is doped titanium oxide. Typical dopants for titanium oxide include Al, Ce, Co, Er, Ga, Gd, Ge, Hf, In, La, Lu, Mg, Mn, Nd, Pr, Sc, Si, Sn, Sr, Y, Zr, or combinations thereof. Typically, the first bottom electrode layer, the second bottom electrode layer, and the high-k dielectric layer are then subjected to a PDA treatment.

A building block layer of molybdenum nitride, 312, (or molybdenum oxy-nitride, 314), is then formed above the dielectric layer, 310. The molybdenum nitride (or molybdenum oxy-nitride) layer has the advantages of low resistivity, high work function, and does not require an anneal treatment to induce the proper crystalline phase.

The base top electrode building block layer, 316, is then formed above the molybdenum nitride (or molybdenum oxy-nitride) layer. The base top electrode layer can include at least one of metals, conductive metal oxides, conductive metal nitrides, conductive metal silicides, conductive metal carbides, and combinations thereof. Examples of suitable conductive metal nitrides include titanium nitride, titanium aluminum nitride, titanium silicon nitride, tantalum nitride, tantalum aluminum nitride, or tantalum silicon nitride, nickel nitride, tungsten nitride, vanadium nitride, molybdenum nitride, and cobalt nitride, or combinations thereof. This completes the formation of the capacitor stack. Typically, the capacitor stack is then subjected to a PMA treatment. In some embodiments, the PMA treatment is performed soon (i.e. before further processing steps) after the forming of the fourth top electrode layer.

The building block layers described above can be combined in a number of ways to form various DRAM MIM stacks.

In some embodiments, building block layers 308, 310, and 312 can be combined to form a stack including: substrate/molybdenum oxide electrode layer/dielectric layer/molybdenum nitride electrode layer (one example—substrate/MoO₂/Al-doped TiO₂/MoN). Various intermediate anneal treatments may be employed as discussed previously. Various dielectric layers may be used as listed above.

In some embodiments, building block layers 308, 310, and 314 can be combined to form a stack including: substrate/molybdenum oxide electrode layer/dielectric layer/molybdenum oxy-nitride electrode layer (one example—substrate/MoO₂/Al-doped TiO₂/MoON). Various intermediate anneal treatments may be employed as discussed previously. Various dielectric layers may be used as listed above.

In some embodiments, building block layers 306, 310, and 312 can be combined to form a stack including: substrate/base bottom electrode layer/dielectric layer/molybdenum nitride electrode layer (one example—substrate/TiN/Al-doped TiO₂/MoN). Various base bottom electrode layers may be used as listed above.

Various intermediate anneal treatments may be employed as discussed previously. Various dielectric layers may be used as listed above.

In some embodiments, building block layers 306, 310, and 314 can be combined to form a stack including: substrate/base bottom electrode layer/dielectric layer/molybdenum oxy-nitride electrode layer (one example—substrate/TiN/Al-doped TiO₂/MoON). Various base bottom electrode layers may be used as listed above. Various intermediate anneal treatments may be employed as discussed previously. Various dielectric layers may be used as listed above.

In some embodiments, building block layers 308, 310, 312, and 316 can be combined to form a stack including: substrate/molybdenum oxide electrode layer/dielectric layer/molybdenum nitride electrode layer/base top electrode layer (one example—substrate/MoO₂/Al-doped TiO₂/MoN/TiN). Various intermediate anneal treatments may be employed as discussed previously. Various dielectric layers may be used as listed above. Various base top electrode layers may be used as listed above.

In some embodiments, building block layers 308, 310, 314, and 316 can be combined to form a stack including: substrate/molybdenum oxide electrode layer/dielectric layer/molybdenum oxy-nitride electrode layer/base top electrode layer (one example—substrate/MoO₂/Al-doped TiO₂/MoON/TiN). Various intermediate anneal treatments may be employed as discussed previously. Various dielectric layers may be used as listed above. Various base top electrode layers may be used as listed above.

In some embodiments, building block layers 306, 308, 310, 312, and 316 can be combined to form a stack including: substrate/base bottom electrode layer/molybdenum oxide electrode layer/dielectric layer/molybdenum nitride electrode layer/base top electrode layer (one example—substrate/TiN/MoO₂/Al-doped TiO₂/MoN/TiN). Various intermediate anneal treatments may be employed as discussed previously. Various base bottom electrode layers may be used as listed above. Various dielectric layers may be used as listed above. Various base top electrode layers may be used as listed above.

In some embodiments, building block layers 306, 308, 310, 314, and 316 can be combined to form a stack including: substrate/base bottom electrode layer/molybdenum oxide electrode layer/dielectric layer/molybdenum oxy-nitride electrode layer/base top electrode layer (one example—substrate/TiN/MoO₂/Al-doped TiO₂/MoON/TiN). Various intermediate anneal treatments may be employed as discussed previously. Various base bottom electrode layers may be used as listed above. Various dielectric layers may be used as listed above. Various base top electrode layers may be used as listed above.

Although the foregoing examples have been described in some detail for purposes of clarity of understanding, the invention is not limited to the details provided. There are many alternative ways of implementing the invention. The disclosed examples are illustrative and not restrictive.

What is claimed:

1. A film stack comprising:
a base bottom electrode layer formed above a surface of a substrate, wherein the base bottom electrode layer comprises a conductive metal nitride material;
a molybdenum oxide bottom electrode layer formed above the base bottom electrode layer;
a dielectric layer formed above the second bottom electrode layer;
a molybdenum nitride layer formed above the dielectric layer; and
a base top electrode layer formed above the molybdenum nitride layer, wherein the base top electrode layer comprises a conductive metal nitride material.

2. The film stack of claim 1, wherein the base bottom electrode layer and the base top electrode layer each comprises one of titanium nitride, titanium aluminum nitride, titanium silicon nitride, tantalum nitride, tantalum aluminum nitride, or tantalum silicon nitride.

3. The film stack of claim 1, wherein the dielectric layer comprises titanium oxide.

4. The film stack of claim 3, wherein the dielectric layer comprises titanium oxide and the dielectric layer further comprises a dopant.

5. The film stack of claim 4, wherein the dopant comprises aluminum.

6. The film stack of claim 5, wherein a concentration of the aluminum is between about 1 atomic % and about 15 atomic % Al as calculated by (Al/(Al+Ti)).

7. The film stack of claim 1, wherein the base bottom electrode layer comprises titanium nitride, the dielectric layer comprises titanium oxide doped with aluminum, and the base top electrode layer comprises titanium nitride.

8. A film stack comprising:
a molybdenum oxide bottom electrode layer formed above a surface of a substrate;
a dielectric layer formed above the second bottom electrode layer;
a molybdenum nitride layer formed above the dielectric layer; and
a base top electrode layer formed above the molybdenum nitride layer, wherein the base top electrode layer comprises a conductive metal nitride material.

9. The film stack of claim 8, wherein the dielectric layer comprises titanium oxide.

10. The film stack of claim 9, wherein the dielectric layer comprises titanium oxide and the dielectric layer further comprises a dopant.

11. The film stack of claim 10, wherein the dopant comprises aluminum.

12. The film stack of claim 11, wherein a concentration of the aluminum is between about 1 atomic % and about 15 atomic % Al as calculated by (Al/(Al+Ti)).

13. The film stack of claim 8, wherein the dielectric layer comprises titanium oxide doped with aluminum, and the base top electrode layer comprises titanium nitride.

14. A film stack comprising:
a molybdenum oxide bottom electrode layer formed above a surface of a substrate;
a dielectric layer formed above the second bottom electrode layer;
a molybdenum oxy-nitride layer formed above the dielectric layer; and
a base top electrode layer formed above the molybdenum oxy-nitride layer, wherein the base top electrode layer comprises a conductive metal nitride material.

15. The film stack of claim 14, wherein the dielectric layer comprises titanium oxide.

16. The film stack of claim 15, wherein the dielectric layer comprises titanium oxide and the dielectric layer further comprises a dopant.

17. The film stack of claim 16, wherein the dopant comprises aluminum.

18. The film stack of claim 17, wherein a concentration of the aluminum is between about 1 atomic % and about 15 atomic % Al as calculated by (Al/(Al+Ti)).

19. The film stack of claim 14, wherein the dielectric layer comprises titanium oxide doped with aluminum, and the base top electrode layer comprises titanium nitride.
